(19) United States
(12) Patent Application Publication
(10) Pub. No.: US 2007/0241427 A1
(43) Pub. Date: Oct. 18, 2007

(54) MESA-TYPE BIPOLAR TRANSISTOR

(76) Inventors: Kazuhiro Mochizuki, Tokyo (JP); Natsuki Yokoyama, Mitaka (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/686,396

(22) Filed: Mar. 15, 2007

(30) Foreign Application Priority Data
Apr. 13, 2006 (JP) 2006-110755

(51) Int. Cl. H01L 31/00; H01L 29/739; H01L 27/082

(52) U.S. Cl. 257/586; 257/197

(57) ABSTRACT

In conventional mesa-type npn bipolar transistors, the improvement of a current gain and the miniaturization of the transistor have been unachievable simultaneously as a result of a trade-off being present between lateral diffusion and recombination of the electrons which have been injected from an emitter layer into a base layer, and a high-density base contact region—emitter mesa distance. In contrast to the above, the present invention is provided as follows:
The gradient of acceptor density in the depth direction of a base layer is greater at the edge of an emitter layer than at the edge of a collector layer. Also, the distance between a first mesa structure including the emitter layer and the base layer, and a second mesa structure including the base layer and the collector layer, is controlled to range from 3 μm to 9 μm. In addition, in order for the above to be implemented with high controllability, the base layer is formed of a first p-type base layer having an acceptor of uniform density, and a second p-type base layer whose density is greater than the uniform acceptor density of the first base layer while having a gradient in the depth direction of the second base layer. These features produce the advantageous effect that it is possible to provide a high-temperature adaptable, power-switching bipolar transistor that ensures a current gain high enough for practical use and is suitable for miniaturization.

### CLAIM OF PRIORITY

The present application claims priority from Japanese application JP 2006-110755 filed on Apr. 13, 2006, the content of which is hereby incorporated by reference into this application.

### BACKGROUND OF THE INVENTION

1. Field of the Invention

The present invention relates generally to bipolar transistors, and more particularly, to a miniature bipolar transistor for electric power switching. According to the invention, a current gain high enough for practical applications can be obtained even at an environmental temperature of above 200° C.

2. Related Art

Conventional power bipolar transistors operable at high temperature employ silicon carbide (SiC) as a semiconductor material, and each have a collector layer, a base layer, and an emitter layer arranged as shown in FIG. 2. FIG. 2 shows a typical example of a longitudinal sectional structural view of such a transistor device. In this example, a collector layer 102 with a donor density of about 2×10¹⁵ cm⁻³, a base layer 103 with an acceptor density of about 1×10¹⁷ cm⁻³, and an emitter layer 104 with a donor density of about 1×10¹⁹ cm⁻³ are epitaxially grown on an n-type substrate 101. A first mesa structure 111 consisting of the emitter layer 104 and the base layer 103, and a second mesa structure consisting of the base layer 103 and the collector layer 102 are formed on the stacked structure. After this, a base electrode 107 is provided via a base contact region 113 having a high-concentration acceptor generated by ion implantation and activation annealing. Also, an emitter electrode 106 is provided directly on the emitter layer 104, and a collector electrode 108 directly on the reverse side of the n-type SiC substrate 101. Reference number 105 denotes an isolation region implanted with acceptor ions to alleviate the concentration of the internal electric field of the collector layer 102 on the second mesa structure 112. Reference number 109 denotes an interlayer insulating film, and 110 an electrical interconnection. A typical example of existing construction is described in IEEE Electron Device Letters, Vol. 24, No. 6, pp. 396-398 (2003).

Non-Patent Document 1: IEEE Electron Device Letters, Vol. 24, No. 6, pp. 396-398 (2003).

### SUMMARY OF THE INVENTION

In the foregoing conventional example of FIG. 2, part of the electrons (in FIG. 2, shown as solid circles) which have been injected from the emitter layer 104 into the base layer 103 are lost at a non-ignorable rate by recombination in the base contact region 113 having crystal defects left therein even after activation annealing. Accordingly, the base contact region 113 acts as a drain for the electrons, and the electron concentration there becomes zero, which generates an electron concentration gradient in the direction of the base contact region 113. Consequently, a large percentage of the electrons which have been injected from the emitter layer 104 into the base layer 103 get diffused in the direction of the base contact region 113 and recombined therein. A current gain is therefore reduced from 35 to 5 when the shortest distance L1 between the side of the first mesa structure 111 and the base contact region 113 decreases to 3 μm or less. This has presented a first problem that maintaining the appropriate current gain and reducing the transistor size cannot be achieved at the same time.

Also, the conventional technique has had a second problem that the optimum range of the shortest distance L2 between the side of the first mesa structure 111 and that of the second mesa structure 112 is not defined. If L2 is too small, part of the electrons which have been injected from the emitter layer 104 into the base layer 103 are diffused into the side of the second mesa structure 112. For this reason, the rate of the electrons which are lost by recombination there increases to a non-ignorable level and the current gain is reduced. Conversely if L2 is too great, the transistor size increases.

In addition, a typical plan view associated with FIG. 2 is shown in FIG. 3. The reference numbers and symbols used in FIG. 3 denote the same constituent elements as in FIG. 2. In these examples, in the construction where the base electrode 107 and the electrical interconnection 110 do not surround the emitter electrode 106 and another electrical interconnection 110, L2 is defined in a region not having the base electrode 107 and the interconnection 110.

The present invention has been made for solving the above two problems, and an object of the invention is to provide a bipolar transistor capable of yielding a current gain high enough for practical use, suitable for size reduction, and usable in high-temperature and power-switching applications.

In order to solve the foregoing first problem, the present invention provides a mesa-type bipolar transistor in which a collector layer made of an n-type semiconductor, a base layer made of a p-type semiconductor, and an emitter layer made of an n-type semiconductor are stacked in that order, the transistor further including a mesa structure formed up of the emitter layer and the base layer; wherein a gradient of acceptor density in a depth direction of the base layer is greater at an edge of the emitter layer than at an edge of the collector layer.

In order to solve the foregoing second problem, the present invention provides a mesa-type bipolar transistor in which a collector layer made of an n-type semiconductor, a base layer made of a p-type semiconductor, and an emitter layer made of an n-type semiconductor are stacked in that order, the transistor further including a mesa structure formed up of the emitter layer and the base layer; wherein a gradient of acceptor density in a depth direction of the base layer is greater at an edge of the emitter layer than at an edge of the collector layer, and the shortest distance between a lateral side of the first mesa structure and that of the second mesa structure ranges from 3 μm to 9 μm. The shortest distance in this case is essentially equivalent to diffusion length of electrons in the base layer of the first mesa structure.

In order for the foregoing first and second problems to be solved with excellent repeatability and high controllability, the above base layer is formed of a first p-type base layer having an acceptor of uniform density, and a second p-type base layer having an acceptor whose density is greater than the uniform acceptor density of the first p-type base layer while at the same time having a gradient in a depth direction of the second p-type base layer.

Silicon carbide (SiC) or gallium nitride (GaN), for example, can be used as a semiconductor material that applies the present invention.

The present invention yields an advantageous effect in that both a current gain high enough for practical use, and miniaturization can be achieved at the same time in a mesa-type power bipolar transistor capable of operating high temperatures. In addition, the construction can be implemented with excellent repeatability and high controllability.

### BRIEF DESCRIPTION OF THE DRAWINGS

FIG. 1 is a longitudinal sectional structural view showing a first embodiment of the present invention;

FIG. 2 is a longitudinal sectional structural view showing a power bipolar transistor based on a conventional technique;

FIG. 3 is a plan view showing the power bipolar transistor based on the conventional technique;

FIG. 4 is a longitudinal sectional structural view showing a second embodiment of the present invention;

FIG. 5 is a in-depth profiles of dacceptor density in a base layer according to the first embodiment of the present invention;

FIG. 6 is a in-depth profiles of acceptor density in a base layer according to the second embodiment of the present invention;

FIG. 7 is a longitudinal sectional structural view that shows a manufacturing process according to the first embodiment of the present invention;

FIG. 8 is a longitudinal sectional structural view that shows the manufacturing process according to the second embodiment of the present invention;

FIG. 9 is a longitudinal sectional structural view that shows the manufacturing process according to the first embodiment of the present invention;

FIG. 10 is a longitudinal sectional structural view that shows the manufacturing process according to the second embodiment of the present invention;

FIG. 11 is a longitudinal sectional structural view that shows the manufacturing process according to the second embodiment of the present invention;

FIG. 12 is a longitudinal sectional structural view that shows the manufacturing process according to the second embodiment of the present invention;

FIG. 13 is a plan view showing the first and second embodiments of the present invention;

FIG. 14 is a longitudinal sectional structural view that shows a manufacturing process according to the second embodiment of the present invention;

FIG. 15 is a longitudinal sectional structural view that shows the manufacturing process according to the second embodiment of the present invention;

FIG. 16 is a longitudinal sectional structural view that shows the manufacturing process according to the second embodiment of the present invention;

FIG. 17 is a longitudinal sectional structural view that shows the manufacturing process according to the second embodiment of the present invention;

FIG. 18 is a longitudinal sectional structural view that shows the manufacturing process according to the second embodiment of the present invention;

FIG. 19 is a longitudinal sectional structural view that shows the manufacturing process according to the second embodiment of the present invention;

FIG. 20 is a plan view showing a fifth embodiment of the present invention;

FIG. 21 is a circuit diagram showing a sixth embodiment of the present invention;

FIG. 22 is a plan view showing the sixth embodiment of the present invention; and

FIG. 23 is a longitudinal sectional structural view of section A-A′ of FIG. 22 which shows the sixth embodiment of the present invention.

### DETAILED DESCRIPTION OF THE PREFERRED EMBODIMENTS

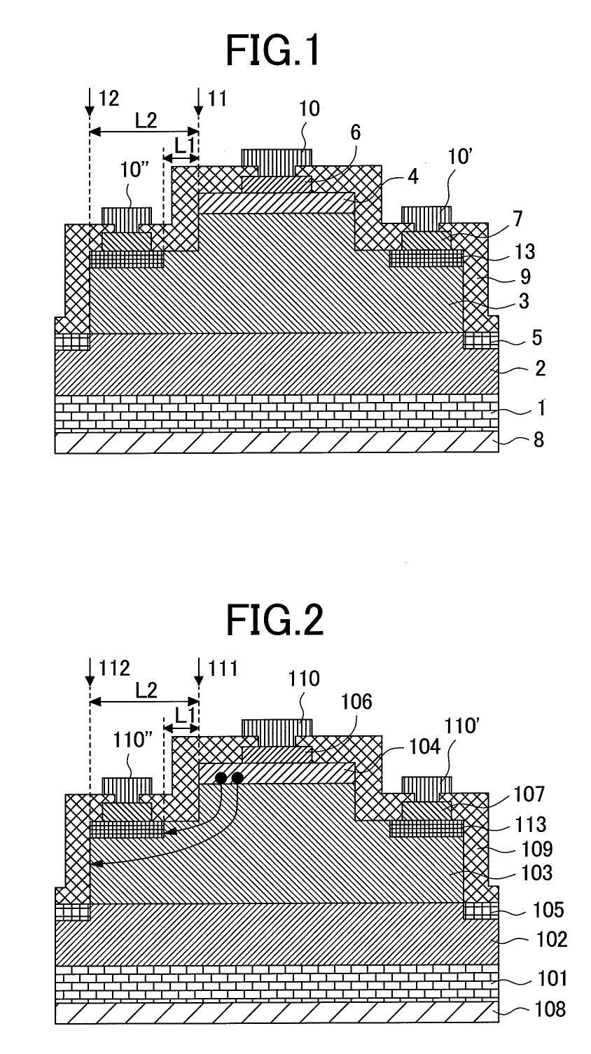

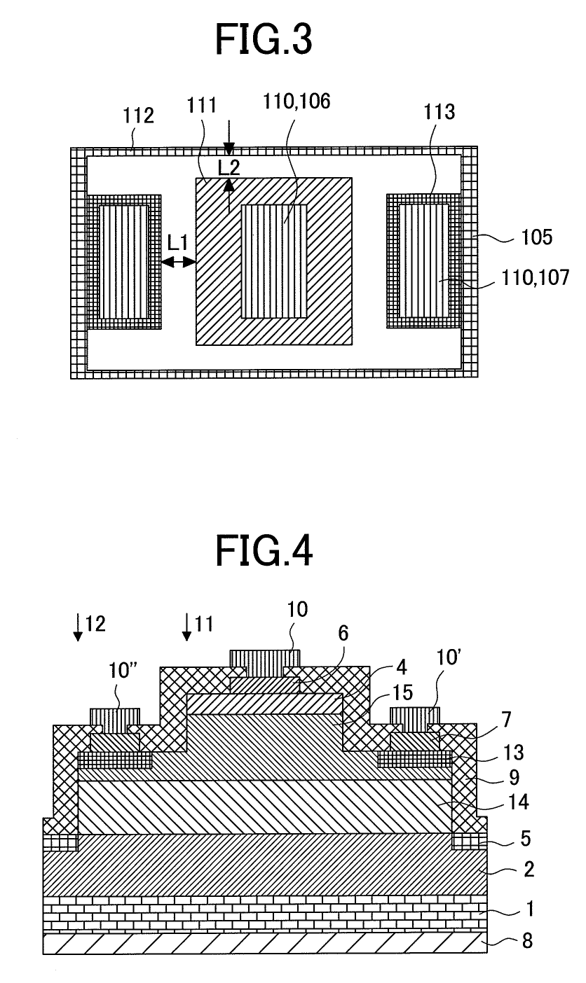

Prior to description of specific embodiments, advantageous effects of various elements of the present invention are outlined below using FIGS. 1 and 4 to 6.

FIG. 1 is a longitudinal sectional structural view of a mesa-type bipolar transistor which uses a combination of elements intended for solving the foregoing first problem, and elements intended for solving the foregoing second problem. For example, a collector layer 2 made of silicon carbide (SiC), a base layer 3 made of p-type SiC, and an emitter layer 4 made of n-type SiC exist in a stacked form on an SiC substrate 1, and the emitter 4 layer and the base layer 3 form a mesa structure 11. Also, ohmic electrodes are formed as follows: an emitter electrode 6 is formed directly on the emitter layer 4; a collector electrode 8 is formed directly on the reverse side of the SiC substrate 1; and a base electrode 7 is formed via a base contact region 13 formed by aluminum (Al) ion implantation. Reference number 10 denotes an electrical interconnection. More specific examples of this transistor construction are detailed in the embodiments below.

Acceptor density distribution in a depth direction of the base layer 3 is shown in FIG. 5. As shown in FIG. 5, a gradient of the acceptor density is greater at an edge of the emitter layer 4 than at an edge of the collector layer 2. Electrons that have been injected from the emitter layer 4 into the base layer 3 are accelerated in the depth direction thereof by a strong built-in field of several kilovolts per centimeter (kV/cm) at the edge of the emitter layer 4, in the base layer 3, and thus, diffusion of the electrons in a direction of the base contact region 113 is reduced to an ignorable level. Consequently, all electrons injected from the emitter layer 4 into the base layer 3 can reach the collector layer 2, with the exception of the electrons that recombine inside the base layer 3 existing in a transistor intrinsic region directly under the emitter layer 4. A current gain of 35 or more can there be obtained, even if L1 that has traditionally needed to be at least 3 μm is reduced to 2 μm or less. This makes it possible to realize a bipolar transistor capable of achieving miniaturization while at the same time having a current gain high enough for practical use.

In FIG. 1, a first mesa structure 11 and a second mesa structure 12 are formed similarly to the conventional technique shown in FIG. 2. When it is assumed that the SiC and GaN that can operate at an environmental temperature of 200° C. or more are used as the materials of the emitter layer 4, base layer 3, and collector layer 2 in FIG. 1, maximum donor density in the emitter layer 4 is approximately 3×10¹⁹ cm⁻³. At the same time, in consideration of the fact that donor density in the collector layer 2 needs to be equal to or more than 1.0×10¹⁶ cm⁻³ and less than 1.0×10¹⁷ cm⁻³ in terms of maintaining a breakdown voltage and reducing a resistance, the base layer 3 must have an acceptor density of equal to or more than 1.0×10¹⁷ cm⁻³ and less than 1.0×10¹⁸ cm³ to avoid the punch-through between the emitter layer 4 and the collector layer 2 due to depletion of the base layer 3 during inverse voltage application, and to ensure a current gain of more than 30, for example. In that case, since diffusion length of the electrons in the base layer 3 is less than 3 μm, if L2 is increased to 3 μm or more, the electrons that have been injected from the emitter layer 4 into the base layer 3 do not become diffused in a lateral-side direction of the second mesa structure 12.

In the meantime, since increasing L2 becomes disadvantageous for miniaturizing the transistor, L2 has its upper limit set to 9 μm, three times the diffusion length, as a distance at which the number of electrons in the base layer 3 becomes almost zero. Thus, miniaturizing a bipolar transistor and obtaining a current gain high enough for practical use can both be achieved at the same time, even for the bipolar transistor having the first and second mesa structures.

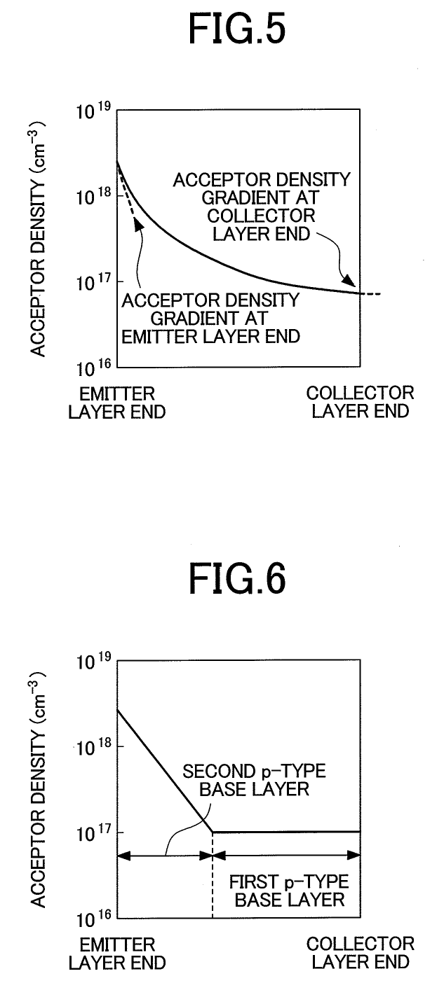

Next, another embodiment of the present invention is described as an example below using FIGS. 4 and 6. FIG. 4 is a longitudinal sectional view of a device according to the present example. FIG. 6 shows an acceptor density distribution in a base layer, between an emitter and a collector. A collector layer 2 made of n-type SiC, a first base layer 14 made of p-type SiC, a second base layer 15 made of p-type SiC, and an emitter layer 4 made of n-type SiC exist on an SiC substrate 1, and the emitter layer 4 and the base layer 3 form a mesa structure 11. Reference number 10 denotes an electrical interconnection. More specific examples of this transistor construction are detailed in the embodiments below.

In the present example, a base layer region is made of the first p-type base layer 14 having an acceptor of uniform density, and the second p-type base layer 15 having an acceptor whose density is higher than the uniform acceptor density of the first p-type base layer and whose density has a gradient in a depth direction of the second p-type base layer. Thus, the concise construction shown as an example in FIG. 6 makes it possible to improve controllability associated with achieving such complex acceptor density distribution in base layer 3 that is shown in FIG. 5, and hence to avoid decreases in repeatability due to non-uniform quality in mass-produced transistor devices.

Next, specific examples of mesa-type bipolar transistors of the present invention, together with respective manufacturing processes, will be described with reference to the accompanying drawings.

### First Embodiment

An npn-type SiC bipolar transistor according to a first embodiment of the present invention, and an associated manufacturing process are described below using FIGS. 1, 5, 7 to 13.

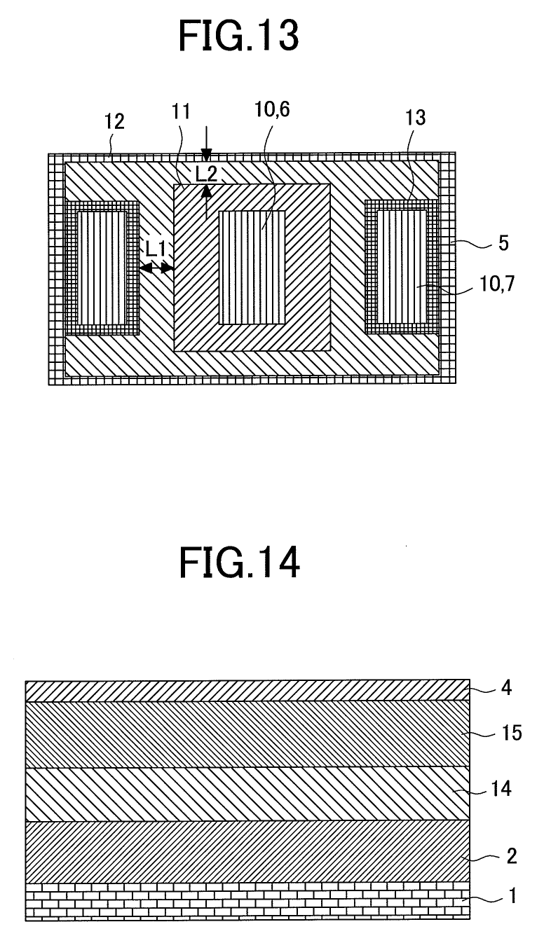

FIG. 1 is a longitudinal sectional structural view of this npn-type SiC bipolar transistor according to the first embodiment of the present invention. FIG. 13 is a plan view of this transistor. In both figures, reference numbers and symbols are used similarly. A collector layer 2 made of n-type SiC with a thickness of 15 μm and a donor (N) density of 2×10¹⁶ cm⁻³, a base layer 3 made of p-type SiC with a thickness of 1 μm, and an emitter layer 4 made of n-type SiC with a thickness of 1 μm and a donor (N) density of 3×10¹⁹ cm⁻³ are formed on an n-type SiC substrate 1 having a (0001) Si surface and a donor (N) density of 3×10¹⁸ cm⁻³. Also, the emitter layer 4 and the base layer 3 form a mesa structure 11. In addition, ohmic electrodes are formed as follows: a nickel/titanium (Ni/Ti) alloyed emitter electrode 6 is formed directly on the emitter layer 4; an Ni/Ti alloyed collector electrode 8 is formed directly on the reverse side of the SiC substrate 1; and a titanium/aluminum (Ti/Al) alloyed base electrode 7 is formed via a base contact region 13 (1×10¹⁹ cm⁻³ in average Al density) formed by Al ion implantation.

In this transistor construction, Al acceptor density in the base layer 3 is as mentioned below. That is to say, the Al acceptor density at an edge of the emitter layer 4 is 3×10¹⁸ cm⁻³, and the Al acceptor density at an edge of the collector layer 2 is 8×10¹⁶ cm⁻³. In terms of acceptor density distribution in a depth direction of the base layer 3, as shown in FIG. 5, a gradient of the acceptor density is greater at the edge of the emitter layer 4 than at the edge of the collector layer 2. Electrons that have been injected from the emitter layer 4 into the base layer 3 are accelerated vertically towards the edge of the collector layer 2, in the base layer 3, by a strong built-in field generated near the emitter layer 4 within the base layer 3, where the acceptor density distribution is formed. Diffusion of the injected electrons in a direction of the base contact region 13 is thus reduced to an ignorable level. Consequently, all electrons injected from the emitter layer 4 into the base layer 3 can reach the collector layer 2, with the exception of the electrons that recombine inside the base layer 3 existing in a transistor intrinsic region directly under the emitter layer 4. A current gain of 35 or more can there be obtained, even if L1 that has traditionally needed to be at least 3 μm is reduced below 2 μm.

Application of the built-in field in the base layer 4 can be continued for complete suppression of lateral electron diffusion. However, the acceptor density at the edge of the collector layer 2, in the base layer 4, is reduced to the same level as or below the donor density in the collector layer 2, and thus a base-collector breakdown voltage is reduced since this voltage is determined by the punch-through due to a deletion layer extending within the base layer. In the present embodiment, therefore, since the gradient of the acceptor density in the baser layer 4 is changed, the acceptor density at the edge of the collector layer 2, in the base layer 4, is maintained at a high level to prevent the breakdown voltage from deteriorating due to the punch-through of the base layer, even when an inverse bias is applied to the base-collector junction.

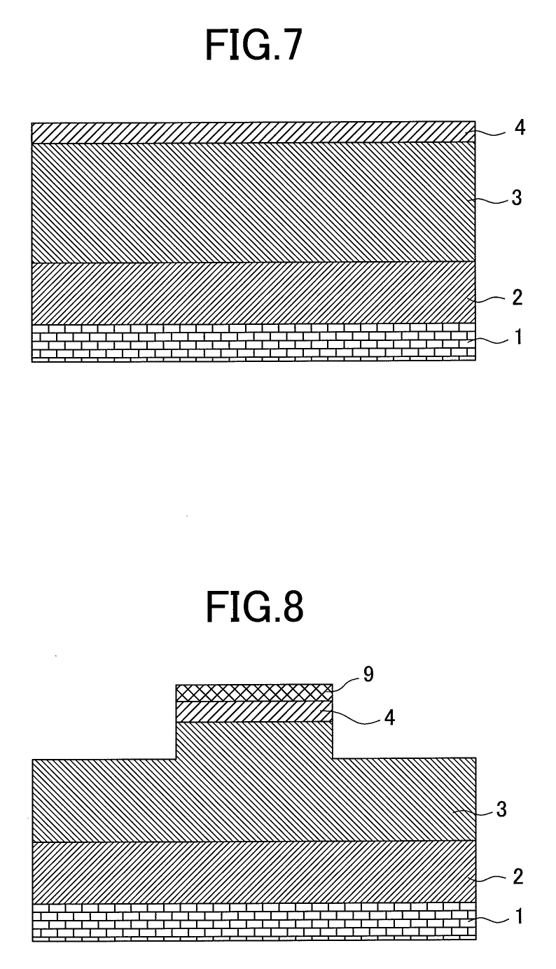

Hereunder, examples of manufacturing process steps for the npn-type SiC bipolar transistor shown in FIGS. 1 and 13 are described using the longitudinal sectional structural views shown in FIGS. 7 to 12.

First, as shown in FIG. 7, the n-type SiC collector layer 2, the p-type SiC base layer 3, and the n-type SiC emitter layer 4 are epitaxially grown on the n-type SiC substrate 1 by chemical vapor deposition.

Next, an SiO₂ film 9 is deposited, then after photolithography and SiO₂ dry etching, a photoresist is removed to form an SiO₂ pattern, and first mesa processing is executed for portions of both the n-type SiC emitter layer 4 and the p-type SiC base layer 3 by dry etching via the SiO₂ pattern. The transistor construction in up to this phase is shown in FIG. 8.

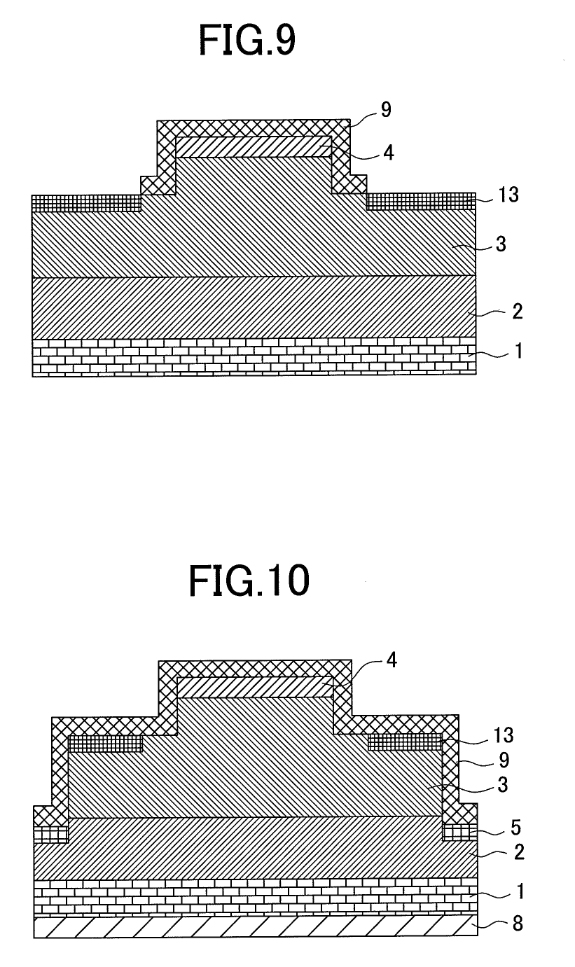

The above is followed by, as shown in FIG. 9, removing the SiO₂ pattern by use of hydrofluoric acid, then depositing an SiO₂ film 9 once again, and after forming an SiO2 pattern by photolithography and SiO₂ dry etching, implanting Al ions into the base contact region 13.

After that, the SiO₂ pattern is removed using hydrofluoric acid, and then annealing is performed at a temperature of 1,500° C. to activate the acceptor within the base contact region 13. After this, a SiO₂ film 9 is deposited and after photolithography and SiO₂ dry etching, a photoresist is removed to form a SiO₂ pattern. Second mesa processing is next executed for both a remainder of the base layer 3 and portions of the collector layer 2 by dry etching. The SiO₂ pattern is removed using hydrofluoric acid, and after a SiO₂ film 9 has been deposited once again, a collector electrode 8 is deposited on the reverse side of the SiC substrate 1. The transistor construction in up to this phase is shown in FIG. 10.

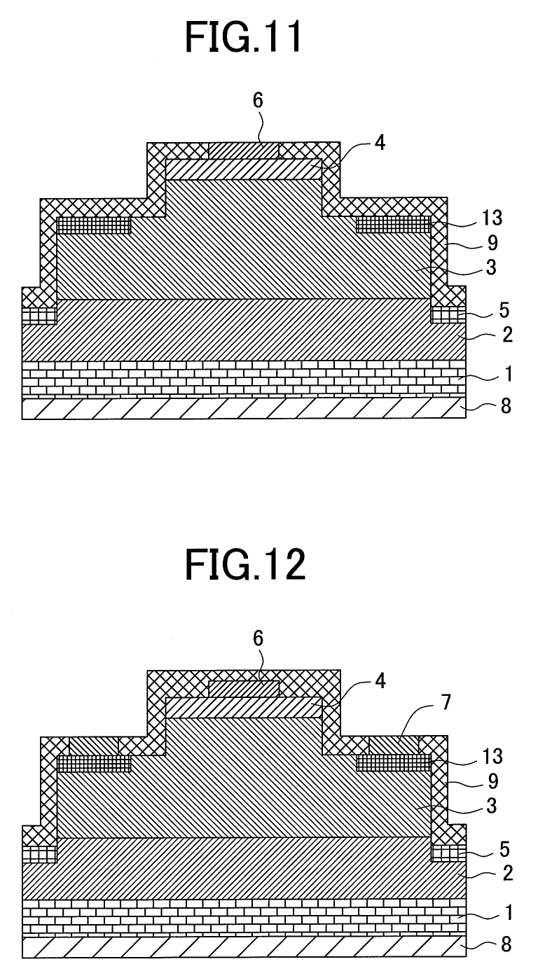

The SiC substrate 1 (sample) is unloaded from the electrode metal evaporator and then is subjected to photolithography and SiO₂ dry etching to hole the SiO₂ section on the surface of the emitter layer 4. After this, an emitter electrode 6 is formed by deposition and lift-off. The transistor construction in up to this phase is shown in FIG. 11.

Next, a SiO₂ film 9 is deposited, then after photolithography and SiO₂ dry etching, a base electrode 7 is formed on the base contact region 13 by deposition and lift-off, and the emitter electrode 6, the base electrode 7, and the collector electrode 8 are each alloyed at 1,000° C. simultaneously. The transistor construction in up to this phase is shown in FIG. 12.

Finally, a SiO₂ film 9 is deposited and then photolithography and SiO₂ dry etching are used to remove a photoresist from necessary sections. After this, Al electrical interconnections 10, 10′, 10″ are deposited and then photolithography and Al dry etching are conducted to complete wiring. In this way, the mesa-type bipolar transistor shown in FIG. 1 can be fabricated.

The present embodiment yields an advantageous effect in that a high-temperature adaptable SiC mesa-type npn bipolar transistor capable of achieving miniaturization and a current gain high enough for practical use can be realized using the built-in field that the acceptor density gradient is created in the base layer 3.

### Second Embodiment

Another npn-type SiC bipolar transistor according to a second embodiment of the present invention, and an associated manufacturing process are described below using FIGS. 1, 5, and 13.

A longitudinal sectional structural view of the npn-type SiC bipolar transistor according to the second embodiment of the present invention, is essentially the same as in FIG. 1. FIG. 13 is a plan view of the transistor. A collector layer 2 made of n-type SiC with a thickness of 15 μm and a donor (N) density of 2×10¹⁶ cm⁻³, a base layer 3 made of p-type SiC with a thickness of 1 μm, and an emitter layer 4 made of n-type SiC with a thickness of 1 μm and a donor (N) density of 3×10¹⁹ cm⁻³ are present on an n-type SiC substrate 1 having a (0001) Si surface and a donor (N) density of 3×10¹⁸ cm³. Also, the emitter layer 4 and the base layer 3 form a mesa structure 11, and the base layer 4 and the collector layer 2 form a second mesa structure 12. In addition, ohmic electrodes are formed as follows: a nickel/titanium (Ni/Ti) alloyed emitter electrode 6 is formed directly on the emitter layer 4; an Ni/Ti alloyed collector electrode 8 is formed directly on the reverse side of the SiC substrate 1; and a titanium/aluminum (Ti/Al) alloyed base electrode 7 is formed via a base contact region 13 (1×10¹⁹ cm⁻³ in average Al density) by Al ion implantation.

In this transistor construction, Al acceptor density in the base layer 3 is essentially the same as in the first embodiment. That is to say, the Al acceptor density at an edge of the emitter layer 4 is 3×10¹⁸ cm⁻³, and the Al acceptor density at an edge of the collector layer 2 is 8×10¹⁶ cm⁻³. In terms of acceptor density distribution in a depth direction of the base layer 3, as shown in FIG. 5, a gradient of the acceptor density is greater at the edge of the emitter layer 4 than at the edge of the collector layer 2. Electrons that have been injected from the emitter layer 4 into the base layer 3 are accelerated vertically towards the edge of the collector layer 2, in the base layer 3, by a strong built-in field near the emitter layer 4 within the base layer 3, where the acceptor density distribution is formed. Diffusion of the injected electrons in a direction of the base contact region 13 is thus reduced to an ignorable level. Consequently, all electrons injected from the emitter layer 4 into the base layer 3 can reach the collector layer 2, with the exception of the electrons that recombine inside the base layer 3 existing in a transistor intrinsic region directly under the emitter layer 4. A current gain of 35 or more can there be obtained, even if L1 that has traditionally needed to be at least 3 μm is reduced below 2 μm.

Application of the built-in field in the base layer 3 can be continued for complete suppression of lateral electron diffusion. However, the acceptor density at the edge of the collector layer 2, in the base layer 3, is reduced to the same level as or below the donor density in the collector layer 2, and thus a base-collector breakdown voltage is reduced since this voltage is determined by punch-through due to a deletion layer extending within the base layer. In the present embodiment, therefore, since the gradient of the acceptor density in the baser layer 3 is changed, the acceptor density at the edge of the collector layer 2, in the base layer 3, is maintained at a high level to prevent the breakdown voltage from deteriorating due to the punch-through of the base layer, even when an inverse bias is applied to the base-collector junction.

Additionally, even when the above acceptor density distribution is adopted, increasing the shortest distance L2 between lateral sides of the first mesa structure 11 and the second mesa structure 12 to at least 3 μm is effective for avoiding the problem that electrons become diffused in a lateral-side direction of the second mesa structure 12 and then recombine to reduce a current gain of the transistor. The advantageous effect that increasing the shortest distance L2 prevents the occurrence of the above problem also applies, even if the electrons that have been injected from the emitter layer 4 into the base layer 3 and accelerated by the built-in field move close to the collector layer 2 in which the built-in field decreases in strength. Provided that L2 is at least 3 μm, the above effect can be sufficiently obtained, but there is a trade-off between this effect and the transistor size. In consideration of a maximum permissible saturation level of this effect, therefore, it is appropriate to limit L2 to a maximum of 9 μm.

Description of the manufacturing process for the npn-type SiC bipolar transistor of the present embodiment is omitted since the process is the same as for the first embodiment.

The present embodiment yields an advantageous effect in that a high-temperature adaptable SiC mesa-type npn bipolar transistor capable of achieving miniaturization and a current gain high enough for practical use can be realized using the built-in field that the acceptor density gradient is created in the base layer 3.

### Third Embodiment

An npn-type GaN bipolar transistor according to a third embodiment of the present invention, and an associated manufacturing process are described below using FIGS. 1, 5, and 10 to 13.

A longitudinal sectional structural view of this npn-type GaN bipolar transistor according to the third embodiment of the present invention is essentially the same as in FIG. 1. FIG. 13 is a plan view of the transistor. A collector layer 2 made of n-type GaN with a thickness of 15 μm and a donor (Si) density of 2×10¹⁶ cm⁻³, a base layer 3 made of p-type GaN with a thickness of 1 μm, and an emitter layer 4 made of n-type GaN with a thickness of 1 μm and a donor (Si) density of 3×10¹⁹ cm⁻³ are present on an n-type GaN substrate 1 having a (0001) Ga surface and a donor (Si) density of 3×10¹⁸ cm⁻³. Also, the emitter layer 4 and the base layer 3 form a mesa structure 11. In addition, ohmic electrodes are formed as follows: a Ti/Al alloyed emitter electrode 6 is formed directly on the emitter layer 4; a Ti/Al alloyed collector electrode 8 is formed directly on the reverse side of the GaN substrate 1; and a Pd/Al alloyed base electrode 7 is formed via a base contact region 13 (1×10¹⁹ cm⁻³ in average Mg density) by Mg ion implantation.

In this transistor construction, Mg acceptor density in the base layer 3 is as mentioned below. That is to say, the Mg acceptor density at an edge of the emitter layer 4 is 3×10¹⁸ cm⁻³, and the Mg acceptor density at an edge of the collector layer 2 is 8×10¹⁶ cm⁻³. In terms of acceptor density distribution in a depth direction of the base layer 3, as shown in FIG. 5, a gradient of the acceptor density is greater at the edge of the emitter layer 4 than at the edge of the collector layer 2. Electrons that have been injected from the emitter layer 4 into the base layer 3 are accelerated vertically towards the edge of the collector layer 2, in the base layer 3, by a strong built-in field near the emitter layer 4, within the base layer 3, where the acceptor density distribution is formed. Diffusion of the injected electrons in a direction of the base contact region 13 is thus reduced to an ignorable level. Consequently, all electrons injected from the emitter layer 4 into the base layer 3 can reach the collector layer 2, with the exception of the electrons that recombine inside the base layer 3 existing in a transistor intrinsic region directly under the emitter layer 4. A current gain of 35 or more can there be obtained, even if L1 that has traditionally needed to be at least 3 μm is reduced below 2 μm.

Application of the built-in field in the base layer 3 can be continued for complete suppression of lateral electron diffusion. However, the acceptor density at the edge of the collector layer 2, in the base layer 3, is reduced to the same level as or below the donor density in the collector layer 2, and thus a base-collector breakdown voltage is reduced since this voltage is determined by punch-through due to a deletion layer extending within the base layer. In the present embodiment, therefore, since the gradient of the acceptor density in the baser layer 3 is changed, the acceptor density at the edge of the collector layer 2, in the base layer 3, is maintained at a high level to prevent the breakdown voltage from deteriorating due to the punch-through of the base layer, even when an inverse bias is applied to the base-collector junction.

Hereunder, examples of manufacturing process steps for the npn-type GaN bipolar transistor shown in FIGS. 1 and 13 are described using the longitudinal sectional structural views shown in FIGS. 7 to 12.

First, as shown in FIG. 7, the n-type GaN collector layer 2, the p-type GaN base layer 3, and the n-type GaN emitter layer 4 are epitaxially grown on the n-type GaN substrate 1 by chemical vapor deposition.

Next, an SiO₂ film 9 is deposited, then after photolithography and SiO₂ dry etching, a photoresist is removed to form an SiO₂ pattern, and first mesa processing is executed for portions of both the n-type GaN emitter layer 4 and the p-type GaN base layer 3 by dry etching via the SiO₂ pattern. The transistor construction in up to this phase is shown in FIG. 8.

The above is followed by, as shown in FIG. 9, removing the SiO₂ pattern by use of hydrofluoric acid, then depositing an SiO₂ film 9 once again, and after forming an SiO2 pattern by photolithography and SiO₂ dry etching, implanting Mg ions into the base contact region 13.

After that, the SiO₂ pattern is removed using hydrofluoric acid, and then annealing is performed at a temperature of 1,500° C. to activate the acceptor within the base contact region 13. After this, a SiO₂ film 9 is deposited and after photolithography and SiO₂ dry etching, a photoresist is removed to form a SiO₂ pattern. Second mesa processing is next executed for both a remainder of the base layer 3 and portions of the collector layer 2 by dry etching. The SiO₂ pattern is removed using hydrofluoric acid, and after a SiO₂ film 9 has been deposited once again, a collector electrode is deposited on the reverse side of the GaN substrate 1. The transistor construction in up to this phase is shown in FIG. 10.

The GaN substrate 1 (sample) is unloaded from the electrode metal evaporator and then is subjected to photolithography and SiO₂ dry etching to hole the SiO₂ section on the surface of the emitter layer 4. After this, an emitter electrode 6 is formed by deposition and lift-off. The transistor construction in up to this phase is shown in FIG. 11.

Next, a SiO₂ film 9 is deposited, then after photolithography and SiO₂ dry etching, a base electrode 7 is formed on the base contact region 13 by deposition and lift-off, and the emitter electrode 6, the base electrode 7, and the collector electrode 8 are each alloyed at 1,000° C. simultaneously. The transistor construction in up to this phase is shown in FIG. 12.

Finally, a SiO₂ film 9 is deposited and then photolithography and SiO₂ dry etching are used to remove a photoresist from necessary sections. After this, Al electrical interconnections are deposited and then photolithography and Al dry etching are conducted. In this way, the mesa-type bipolar transistor shown in FIG. 1 can be fabricated.

The present embodiment yields an advantageous effect in that a high-temperature adaptable GaN mesa-type npn bipolar transistor capable of achieving miniaturization and a current gain high enough for practical use can be realized using the built-in field that the acceptor density gradient is created in the base layer 3.

### Fourth Embodiment

Another npn-type GaN bipolar transistor according to a fourth embodiment of the present invention, and an associated manufacturing process are described below using FIGS. 1, 5, and 13.

A longitudinal sectional structural view of this npn-type GaN bipolar transistor according to the third embodiment of the present invention, is essentially the same as in FIG. 1. FIG. 13 is a plan view of the transistor. A collector layer 2 made of n-type GaN with a thickness of 15 μm and a donor (Si) density of 2×10¹⁶ cm⁻³, a base layer 3 made of p-type GaN with a thickness of 1 μm, and an emitter layer 4 made of n-type GaN with a thickness of 1 μm and a donor (Si) density of 3×10¹⁹ cm⁻³ are present on an n-type GaN substrate 1 having a (0001) Ga surface and a donor (N) density of 3×10¹⁸ cm⁻³. Also, the emitter layer 4 and the base layer 3 form a mesa structure 11, and the base layer 3 and the collector layer 2 form a mesa structure 12. In addition, ohmic electrodes are formed as follows: a Ti/Al alloyed emitter electrode 6 is formed directly on the emitter layer 4; a Ti/Al alloyed collector electrode 8 is formed directly on the reverse side of the GaN substrate 1; and a Pd/Al alloyed base electrode 7 is formed via a base contact region 13 (1×10¹⁹ cm⁻³ in average Mg density) by Mg ion implantation. In this transistor construction, Mg acceptor density in the base layer 3 is as mentioned below. That is to say, the Mg acceptor density at an edge of the emitter layer 4 is 3×10¹⁸ cm⁻³, and the Mg acceptor density at an edge of the collector layer 2 is 8×10¹⁶ cm⁻³. In terms of acceptor density distribution in a depth direction of the base layer 3, as shown in FIG. 5, a gradient of the acceptor density is greater at the edge of the emitter layer 4 than at the edge of the collector layer 2. Electrons that have been injected from the emitter layer 4 into the base layer 3 are accelerated vertically towards the edge of the collector layer 2, in the base layer 3, by a strong built-in field near the emitter layer 4, within the base layer 3, where the acceptor density distribution is formed. Diffusion of the injected electrons in a direction of the base contact region 13 is thus reduced to an ignorable level. Consequently, all electrons injected from the emitter layer 4 into the base layer 3 can reach the collector layer 2, with the exception of the electrons that recombine inside the base layer 3 existing in a transistor intrinsic region directly under the emitter layer 4. A current gain of 35 or more can there be obtained, even if L1 that has traditionally needed to be at least 3 μm is reduced below 2 μm.

Application of the built-in field in the base layer 4 can be continued for complete suppression of lateral electron diffusion. However, the acceptor density at the edge of the collector layer 2, in the base layer 3, is reduced to the same level as or below the donor density in the collector layer 2, and thus a base-collector breakdown voltage is reduced since this voltage is determined by punch-through due to a deletion layer extending within the base layer. In the present embodiment, therefore, since the gradient of the acceptor density in the baser layer 4 is changed, the acceptor density at the edge of the collector layer 2, in the base layer 3, is maintained at a high level to prevent the breakdown voltage from deteriorating due to the punch-through of the base layer, even when an inverse bias is applied to the base-collector section.

Additionally, even when the above acceptor density distribution is adopted, increasing the shortest distance L2 between lateral sides of the first mesa structure 11 and the second mesa structure 12 to at least 3 μm is effective for avoiding the problem that electrons become diffused in a lateral-side direction of the second mesa structure 12 and then recombine to reduce a current gain of the transistor. The advantageous effect that increasing the shortest distance L2 prevents the occurrence of the above problem also applies, even if the electrons that have been injected from the emitter layer 4 into the base layer 3 and accelerated by the built-in field move close to the collector layer 2 in which the built-in field decreases in strength. Provided that L2 is at least 3 μm, the above effect can be sufficiently obtained, but there is a trade-off between this effect and the transistor size. In consideration of a maximum permissible saturation level of this effect, therefore, it is appropriate to limit L2 to a maximum of 9 μm.

Description of the manufacturing process for the npn-type bipolar transistor of the present embodiment is omitted since the process is the same as for the first embodiment.

The present embodiment yields an advantageous effect in that a high-temperature adaptable GaN mesa-type npn bipolar transistor capable of achieving miniaturization and a current gain high enough for practical use can be realized using the built-in field that the acceptor density gradient is created in the base layer 3.

### Fifth Embodiment

Yet another npn-type SiC bipolar transistor that is a fifth embodiment of the present invention, and an associated manufacturing process are described below using FIGS. 4, 6, and 14 to 19.

FIG. 4 is a longitudinal sectional structural view of this npn-type SiC bipolar transistor according to the fifth embodiment of the present invention. FIG. 13 is a plan view of this transistor. A collector layer 2 made of n-type SiC with a thickness of 15 μm and a donor (N) density of 2×10¹⁶ cm⁻³, a first base layer 14 made of p-type SiC with a thickness of 0.6 μm, a second base layer 15 made of p-type SiC with a thickness of 0.4 μm, and an emitter layer 4 made of n-type SiC with a thickness of 1 μm and a donor (N) density of 3×10¹⁸ cm⁻³ are present on an n-type SiC substrate 1 having a (0001) Si surface and a donor (N) density of 3×10¹⁸ cm⁻³. Also, the emitter layer 4 and the base layer 3 form a mesa structure 11. In addition, ohmic electrodes are formed as follows: a nickel/titanium (Ni/Ti) alloyed emitter electrode 6 is formed directly on the emitter layer 4; an Ni/Ti alloyed collector electrode 8 is formed directly on the reverse side of the SiC substrate 1; and a titanium/aluminum (Ti/Al) alloyed base electrode 7 is formed via a base contact region 13 (1×10¹⁹ cm⁻³ in average Al density) by Al ion implantation. The base contact region exists inside the second layer 15 and is not in contact with the first base layer 14.

In this transistor construction, Al acceptor density in the first base layer 14 and that of the second base layer 15 are as shown in FIG. 6. That is to say, the second base layer 15 has an Al acceptor density of 3×10¹⁸ cm⁻³ at an edge of the emitter layer 4, and an Al acceptor density of 1×10¹⁷ cm⁻³ at an edge of the first collector layer 14. These indicate that the acceptor density decreases in a depth direction of the base layer. The first base layer 14 has a constant Al acceptor density of 1.0×10¹⁷ cm⁻³.

Electrons that have been injected from the emitter layer 4 into the second base layer 15 are accelerated vertically towards the edge of the first base layer 14 by a strong built-in field where the acceptor density distribution is formed in the second base layer 15. Diffusion of the injected electrons in a direction of the base contact region 13 is thus reduced to an ignorable level. Consequently, all electrons injected from the emitter layer 4 into the second base layer 15 can reach the collector layer 2, with the exception of the electrons that recombine in the first base layer 14 and in the second base layer 15 existing in a transistor intrinsic region directly under the emitter layer 4. A current gain of 35 or more can there be obtained, even if L1 that has traditionally needed to be at least 3 μm is reduced below 2 μm.

Hereunder, examples of manufacturing process steps for the npn-type SiC bipolar transistor shown in FIGS. 4 and 13 are described using the longitudinal sectional structural views shown in FIGS. 14 to 19.

First, as shown in FIG. 14, the n-type SiC collector layer 2, the p-type SiC first base layer 14, the p-type SiC second base layer 15, and the n-type SiC emitter layer 4 are epitaxially grown on the n-type SiC substrate 1 by chemical vapor deposition.

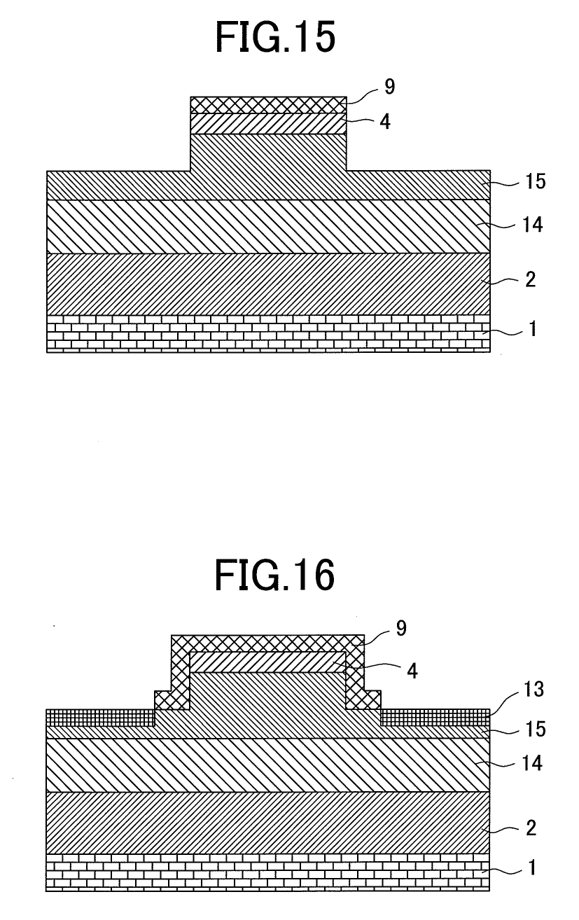

Next, a SiO₂ film 9 is deposited, then after photolithography and SiO₂ dry etching, a photoresist is removed to form a SiO₂ pattern, and first mesa processing is executed for portions of both the n-type SiC emitter layer 4 and the p-type SiC second base layer 15 by dry etching via the SiO₂ pattern. The transistor construction in up to this phase is shown in FIG. 15.

The above is followed by, as shown in FIG. 16, removing the SiO₂ pattern by use of hydrofluoric acid, then depositing a SiO₂ film 9 once again, and after forming a SiO₂ pattern by photolithography and SiO₂ dry etching, implanting Al ions into the base contact region 13.

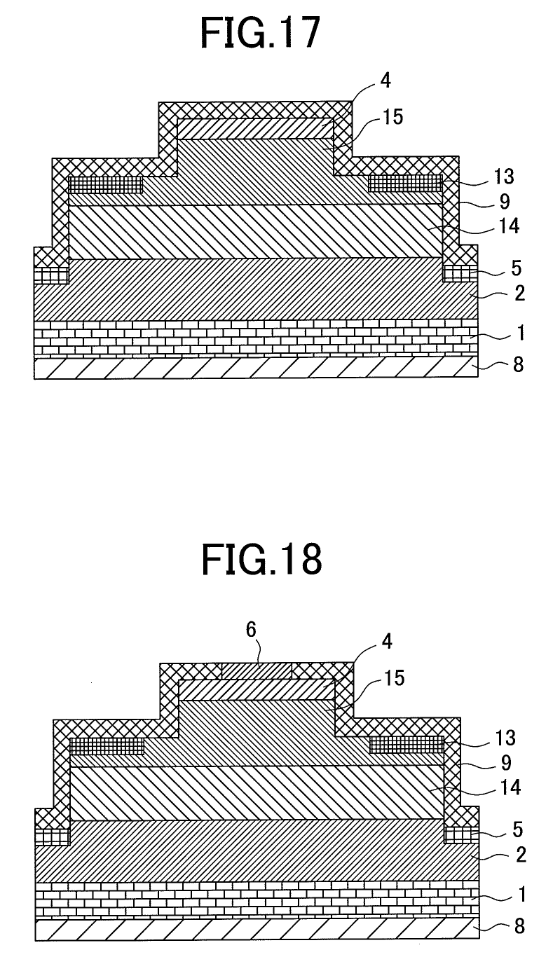

After that, the SiO₂ pattern is removed using hydrofluoric acid, and then annealing is performed at a temperature of 1,500° C. to activate the acceptor within the base contact region 13. After this, a SiO₂ film 9 is deposited and after photolithography and SiO₂ dry etching, a photoresist is removed to form a SiO₂ pattern. Second mesa processing is next executed for both a remainder of the second base layer 15 and portions of the first base layer 14 and the collector layer 2 by dry etching. The SiO₂ pattern is removed using hydrofluoric acid, and after a SiO2 film 9 has been deposited once again, a collector electrode 8 is deposited on the reverse side of the SiC substrate 1. The transistor construction in up to this phase is shown in FIG. 17.

The SiC substrate 1 (sample) is unloaded from the electrode metal evaporator and then provided with photolithography and SiO₂ dry etching to hole the SiO₂ section on the surface of the emitter layer 4. After this, an emitter electrode 6 is formed by deposition and lift-off. The transistor construction in up to this phase is shown in FIG. 18.

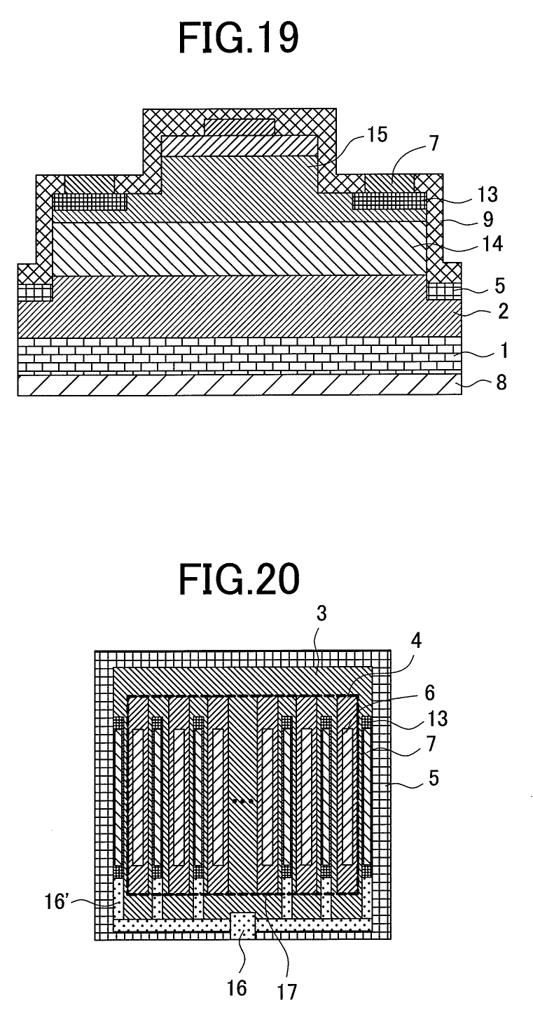

Next, a SiO₂ film 9 is deposited, then after photolithography and SiO₂ dry etching, a base electrode 7 is formed on the base contact region 13 by deposition and lift-off, and the emitter electrode 6, the base electrode 7, and the collector electrode 8 are each alloyed at 1,000° C. simultaneously. The transistor construction in up to this phase is shown in FIG. 19.

Finally, a SiO₂ film 9 is deposited and then photolithography and SiO₂ dry etching are conducted to remove a photoresist. After this, Al electrical interconnections are deposited and then photolithography and Al dry etching are conducted. In this way, the mesa-type bipolar transistor shown in FIG. 1 can be fabricated.

The present embodiment yields an advantageous effect in that a high-breakdown-voltage, high-temperature adaptable SiC mesa-type npn bipolar transistor capable of achieving miniaturization and a current gain high enough for practical use can be realized by combining the first base layer that is a high-voltage blocking layer, and then second base layer that is a built-in field layer.

### Sixth Embodiment

Yet another npn-type GaN bipolar transistor according to a sixth embodiment of the present invention, and an associated manufacturing process are described below using FIGS. 4, 6, and 14 to 19.

A longitudinal sectional structural view of this npn-type GaN bipolar transistor according to the sixth embodiment of the present invention, is essentially the same as in FIG. 4. FIG. 13 is a plan view of this transistor. A collector layer 2 made of n-type GaN with a thickness of 15 μm and a donor (Si) density of 2×10¹⁶ cm⁻³, a first base layer 14 made of p-type GaN with a thickness of 0.6 μm, a second base layer 15 made of p-type GaN with a thickness of 0.4 μm, and an emitter layer 4 made of n-type GaN with a thickness of 1 μm and a donor (Si) density of 3×10¹⁹ cm⁻³ are present on an n-type GaN substrate 1 having a (0001) Si surface and a donor (Si) density of 3×10¹⁸ cm⁻³. Also, the emitter layer 4 and the base layer 3 form a mesa structure 11. In addition, ohmic electrodes are formed as follows: a Ti/Ni alloyed emitter electrode 6 is formed directly on the emitter layer 4; a Ti/Al alloyed collector electrode 8 is formed directly on the reverse side of the GaN substrate 1; and a Pd/Al alloyed base electrode 7 is formed via a base contact region 13 (1×10¹⁹ cm³ in average Mg density) by Mg ion implantation. The base contact region exists inside the second layer 15 and is not in contact with the first base layer 14.

In this transistor construction, Al acceptor density in the first base layer 14 and that of the second base layer 15 are as shown in FIG. 6. That is to say, the second base layer 15 has an Mg acceptor density of 3×10¹⁸ cm⁻³ at an edge of the emitter layer 4, and an Mg acceptor density of 1×10¹⁷ cm⁻³ at an edge of the first collector layer 14. These indicate that the acceptor density decreases in a depth direction of the base layer. The first base layer 14 has a constant Mg acceptor density of 1×10¹⁷ cm⁻³.

Electrons that have been injected from the emitter layer 4 into the second base layer 15 are accelerated vertically towards the edge of the first base layer 14 by a strong built-in field that the acceptor density distribution is formed in the second base layer 15. Diffusion of the injected electrons in a direction of the base contact region 13 is thus reduced to an ignorable level. Consequently, all electrons injected from the emitter layer 4 into the second base layer 15 can reach the collector layer 2, with the exception of the electrons that recombine in the first base layer 14 and in the second base layer 15 existing in a transistor intrinsic region directly under the emitter layer 4. A current gain of at least 35 can there be obtained, even if L1 that has traditionally needed to be at least 3 μm is reduced to 2 μm or less.

Hereunder, examples of manufacturing process steps for the npn-type GaN bipolar transistor shown in FIGS. 4 and 13 are described using the longitudinal sectional structural views shown in FIGS. 14 to 19.

First, as shown in FIG. 14, the n-type GaN collector layer 2, the p-type GaN first base layer 14, the p-type GaN second base layer 15, and the n-type GaN emitter layer 4 are epitaxially grown on the n-type GaN substrate 1 by chemical vapor deposition.

Next, a SiO₂ film 9 is deposited, then after photolithography and SiO₂ dry etching, a photoresist is removed to form a SiO₂ pattern, and first mesa processing is executed for portions of both the n-type GaN emitter layer 4 and the p-type GaN second base layer 15 by dry etching via the SiO₂ pattern. The transistor construction in up to this phase is shown in FIG. 15.

The above is followed by, as shown in FIG. 16, removing the SiO₂ pattern by use of hydrofluoric acid, then depositing a SiO₂ film 9 once again, and after forming an SiO₂ pattern by photolithography and SiO₂ dry etching, implanting Mg ions into the base contact region 13.

After that, the SiO₂ pattern is removed using hydrofluoric acid, and then annealing is performed at a temperature of 1,500° C. to activate the acceptor within the base contact region 13. After this, a SiO₂ film 9 is deposited and after photolithography and SiO2 dry etching, a photoresist is removed to form a SiO₂ pattern. Second mesa processing is next executed for both a remainder of the second base layer 15 and portions of the first base layer 14 and the collector layer 2 by dry etching. The SiO₂ pattern is removed using hydrofluoric acid, and after a SiO₂ film 9 has been deposited once again, a collector electrode is deposited on the reverse side of the GaN substrate 1. The transistor construction in up to this phase is shown in FIG. 17.

The GaN substrate 1 (sample) is unloaded from the electrode metal evaporator and then is subjected to photolithography and SiO₂ dry etching to hole the SiO₂ section on the surface of the emitter layer 4. After this, an emitter electrode 6 is formed by deposition and lift-off. The transistor construction in up to this phase is shown in FIG. 18.

Next, a SiO₂ film 9 is deposited, then after photolithography and SiO₂ dry etching, a base electrode 7 is formed on the base contact region 13 by deposition and lift-off, and the emitter electrode 6, the base electrode 7, and the collector electrode 8 are each alloyed at 1,000° C. simultaneously. The transistor construction in up to this phase is shown in FIG. 19.

Finally, a SiO₂ film 9 is deposited and then photolithography and SiO₂ dry etching are conducted to remove a photoresist. After this, Al electrical interconnections are deposited and then photolithography and Al dry etching are conducted. In this way, the mesa-type bipolar transistor shown in FIG. 1 can be fabricated.

The present embodiment yields an advantageous effect in that a high-breakdown-voltage, high-temperature adaptable GaN mesa-type npn bipolar transistor capable of achieving miniaturization and a current gain high enough for practical use can be realized by combining the first base layer that is a high-voltage blocking layer, and the second base layer that is a built-in field layer.

### Seventh Embodiment

In accordance with the plan view shown in FIG. 20, a multi-finger-type bipolar transistor for power switching is described below as a seventh embodiment of the present invention.

The multi-finger type bipolar transistor according to the present embodiment is constructed by connecting a plurality of mesa-type bipolar transistors in parallel on a substrate 1, as shown in FIG. 20. These mesa-type bipolar transistors can be used in the first to sixth embodiments. In FIG. 20, base electrode electrical interconnections are aggregated in integrated form at a base pad 16. Also, an emitter pad 20 is shown as a hollow rectangle with its periphery denoted by a discontinuous line. The emitter pad 20 is shown in this way to indicate that emitter electrode electrical interconnections and those of the base electrode electrical interconnections are present under the emitter pad 20. A more specific example of planar construction of the multi-finger-type bipolar transistor is as described below. That is to say, in this transistor construction, an emitter electrode 6 formed on an n-type emitter layer 4, and a p-type base contact region 13 and base electrode 7 formed on a p-type base layer 3 are arranged in an alternate fashion, and a termination region 5 is formed only on chip periphery, not on a finger-by-finger basis. An emitter pad 17 has only an outer surface thereof shown as a discontinuous line.

The present embodiment yields an advantageous effect in that it is possible to realize a multi-finger-type bipolar transistor capable of achieving miniaturization simultaneously with a current gain high enough for practical use, and switching electric power, even at high temperature.

### Eighth Embodiment

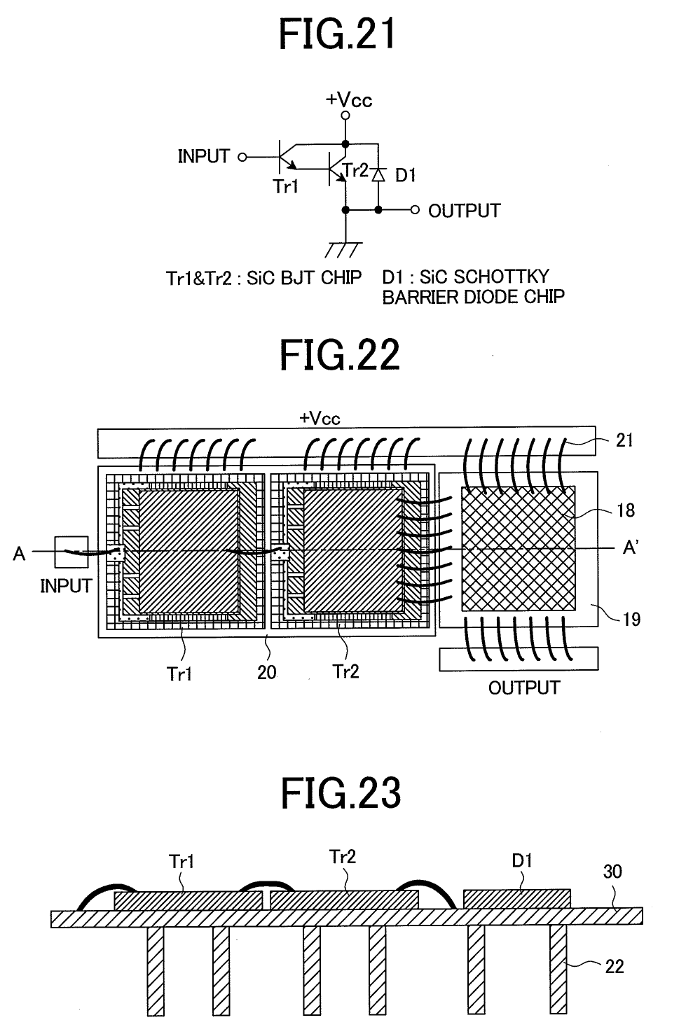

A high-temperature adaptable inverter according to an eighth embodiment of the present invention is described below using FIGS. 21 to 23.

FIG. 21 is an equivalent circuit diagram of the inverter according to the present embodiment. Reference symbols Tr1 and Tr2 both denote the power-switching multi-finger-type bipolar transistor shown in the seventh embodiment, and D1 denotes a commercially available SiC Schottky barrier diode. An effective current gain exceeding 1,000 can be obtained using the Darlington-connected transistors Tr1 and Tr2. A voltage source +Vcc is connected at its input side to a terminal to which a cathode of D1 and a collector common to Tr1 and Tr2 are connected, and at its output side to a terminal to which an emitter of Tr2 and an anode of D1 are connected.

FIG. 22 is a plan view that shows the layout of constituent elements, based on the circuit diagram of FIG. 21. Reference number 18 denotes a cathode electrode; 19, an anode electrode connection pattern; 20, a collector electrode connection pattern; and 21, a bonding wire. In FIG. 22, “Tr1”, Tr2”, “Input”, “Output”, and “Vcc” denote the transistor Tr1, transistor Tr2, input side, output side, and voltage source, respectively, that are shown in the circuit diagram of FIG. 21. FIG. 23 is a longitudinal sectional structural view that shows section A-A′ of FIG. 22. The Tr1, Tr2, and D1 chips electrically connected on a package substrate 30 having heat-sink fins 22 are connected to one another via bonding wires 21.

The present embodiment yields an advantageous effect in that since multi-finger-type bipolar transistors capable of achieving miniaturization simultaneously with a current gain high enough for practical use, and switching electric power, even at high temperature, is employed, an inverter featuring a low electrical loss ratio which has heretofore been difficult to obtain at high temperatures exceeding 200° C. can be realized, even at these high temperatures.

The meanings of the reference numbers and symbols used in the accompanying drawings are shown below.

1, 101 . . . Substrate, 2, 102 . . . n-type collector layer, 3, 103 . . . p-type base layer, 4, 104 . . . n-type emitter layer, 5, 105 . . . Termination region, 6, 106 . . . Emitter electrode, 7, 107 . . . Base electrode, 8, 108 . . . Collector electrode, 9, 109 . . . Insulating film, 10, 10′, 10″, 110, 110′, 110″ . . . Electrical interconnection, 11, 111 . . . First mesa, 12, 112, . . . Second mesa, 13 . . . p-type base contact region, 14 . . . First p-type base layer, 15 . . . Second p-type base layer, 16 . . . Base pad, 16′ . . . Base electrical interconnection, 17 . . . Emitter pad, 18 . . . Cathode electrode, 19 . . . Anode electrode connection pattern, 20 . . . Collector electrode connection pattern, 21 . . . Bonding wire, 22 . . . Heat-sink fin.

What is claimed is:

1. A mesa-type bipolar transistor in which a collector layer formed of an n-type semiconductor, a base layer formed of a p-type semiconductor, and an emitter layer formed of an n-type semiconductor are stacked in order, the transistor comprising:
a first mesa structure including the emitter layer and the base layer;
wherein:
a gradient of acceptor density in a depth direction of the base layer, with respect to a stacking direction of the semiconductor layers, is greater at an edge of the emitter layer than at an edge of the collector layer.

2. The mesa-type bipolar transistor according to claim 1, further comprising:
a second mesa structure including the emitter layer and the base layer;
wherein:
the shortest distance between a lateral side of the first mesa structure and a lateral side of the second mesa structure ranges from 3 μm to 9 μm.

3. The mesa-type bipolar transistor according to claim 1, wherein the base layer comprises a first p-type base layer with an uniform acceptor density, and a second p-type base layer with an acceptor density that is greater than the uniform density and that has a gradient in a depth direction of the second p-type base layer.

4. The mesa-type bipolar transistor according to claim 2, wherein the base layer comprises a first p-type base layer with an acceptor density being uniform, and a second p-type base layer with an acceptor whose density is greater than the uniform density and whose density has a gradient in a depth direction of the second p-type base layer.

5. The mesa-type bipolar transistor according to claim 2, wherein the shortest distance between the lateral side of the first mesa structure and the lateral side of the second mesa structure is greater than diffusion length of electrons in the first p-type base layer.

6. The mesa-type bipolar transistor according to claim 4, wherein the shortest distance between the lateral side of the first mesa structure and the lateral side of the second mesa structure is greater than diffusion length of electrons in the first p-type base layer.

7. The mesa-type bipolar transistor according to claim 1, wherein:
the base layer has a region with a small width on one side on which the base layer abuts the emitter layer, the emitter layer existing on the region with the small width of the base layer; and
the gradient of the acceptor density in the depth direction of the base layer, with respect to the stacking direction of the semiconductor layers, is greater at the edge of the emitter layer than at the edge of the collector layer.

8. The mesa-type bipolar transistor according to claim 1, wherein:
the base layer includes a first base layer formed on the collector layer, and a second base layer formed at an upper section of the first base layer;
the second base layer has a region with a small width on one side on which the second base layer abuts the emitter layer, the emitter layer existing on the region with the small width of the second base layer; and
the gradient of the acceptor density in the depth direction of the base layer, with respect to the stacking direction of the semiconductor layers, is greater at the edge of the emitter layer than at the edge of the collector layer.

9. The mesa-type bipolar transistor according to claim 1, wherein:
the collector layer has a region with a small width on one side on which the collector layer abuts the base layer, the base layer existing on the region with the small width of the collector layer;
the base layer has a region with a small width on a side on which the base layer abuts the emitter layer on the same side as the side of the region with the small width of the collector layer, the emitter layer existing on the region with the narrowed width of the base layer, the emitter layer existing on the region with the small width of the base layer; and
the gradient of the acceptor density in the depth direction of the base layer, with respect to the stacking direction of the semiconductor layers, is greater at the edge of the emitter layer than at the edge of the collector layer.

10. The mesa-type bipolar transistor according to claim 1, wherein:
the collector layer has a region with a small width on one side on which the collector layer abuts the base layer, the base layer existing on the region with the small width of the collector layer;
the base layer includes a first base layer formed on the collector layer, and a second base layer formed at an upper section of the first base layer;
the second base layer has a region with a small width on a side on which the second base layer abuts the emitter layer on the same side as the side of the region with the small width of the collector layer, the emitter layer existing on the region with the small width of the second base layer; and
the gradient of the acceptor density in the depth direction of the base layer, with respect to the stacking direction of the semiconductor layers, is greater at the edge of the emitter layer than at the edge of the collector layer.

11. The mesa-type bipolar transistor according to claim 1, wherein:
the collector layer is an n-type SiC layer, the base layer is a p-type SiC layer, and the emitter layer is an n-type SiC layer.

12. The mesa-type bipolar transistor according to claim 2, wherein:
the collector layer is an n-type SiC layer, the base layer is a p-type SiC layer, and the emitter layer is an n-type SiC layer.

13. The mesa-type bipolar transistor according to claim 11, wherein the collector layer is mounted on an n-type SiC substrate.

14. The mesa-type bipolar transistor according to claim 1, wherein:
the collector layer is an n-type GaN layer, the base layer is a p-type GaN layer, and the emitter layer is an n-type GaN layer.

15. The mesa-type bipolar transistor according to claim 2, wherein:
the collector layer is an n-type GaN layer, the base layer is a p-type GaN layer, and the emitter layer is an n-type GaN layer.

16. The mesa-type bipolar transistor according to claim 11, wherein the collector layer is mounted on an n-type GaN substrate.
